(19) United States
(12) Patent Application Publication
(10) Pub. No.: US 2025/0098548 A1
(43) Pub. Date: Mar. 20, 2025

(54) SEMICONDUCTOR DEVICE AND METHOD FOR FABRICATING THE SAME

(71) Applicant: SK hynix Inc., Icheon-si (KR)

(72) Inventor: Cha Deok DONG, Icheon-si (KR)

(21) Appl. No.: 18/584,969

(22) Filed: Feb. 22, 2024

(30) Foreign Application Priority Data
Sep. 19, 2023 (KR) 10-2023-0124745

(51) Int. Cl. H10N 50/80; H10B 61/00; H10N 50/01; H10N 50/10

(52) U.S. Cl. CPC H10N 50/80; H10B 61/10; H10N 50/01; H10N 50/10

(57) ABSTRACT

Semiconductor devices and methods for fabricating semiconductor memory devices are disclosed. In an embodiment, a semiconductor device includes: a selector pattern configured to exhibit a threshold switching behavior; an insulating layer structured to a sidewall of the selector pattern and include an opening disposed within the insulating layer over the selector pattern; and an electrode formed in the opening to a thickness that blocks an entrance of the opening and does not completely fill the opening.

### CROSS-REFERENCE TO RELATED APPLICATION

This patent document claims the priority and benefits of Korean Patent Application No. 10-2023-0124745 filed on Sep. 19, 2023, which is incorporated herein by reference in its entirety.

### TECHNICAL FIELD

The technology disclosed in this patent document relates to a semiconductor technology, and more particularly, to a semiconductor device including a memory cell having a selector, and a method for fabricating the same.

### BACKGROUND

With the recent trend toward miniaturization, low power consumption, high performance, and multi-functionality in the electrical and electronics industry, the semiconductor manufacturers are focusing on high-performance, high capacity semiconductor devices. Examples of such high-performance, high-capacity semiconductor devices include semiconductor devices that can store data by switching between different resistance states according to an applied voltage or current, such as resistive random access memory (RRAM), phase change random access memory (PRAM), ferroelectric random access memory (FRAM), magnetic random access memory (MRAM), and electronic fuse (E-fuse).

### SUMMARY

In an embodiment, a semiconductor device may include: a selector pattern configured to exhibit a threshold switching behavior by exhibiting different electrical conducting characteristics in response to an applied voltage with respect to a threshold voltage; an insulating layer structured to surround a sidewall of the selector pattern and include an opening disposed within the insulating layer over the selector pattern; and an electrode formed in the opening to a thickness that blocks an entrance of the opening and does not completely fill the opening.

In an embodiment, a method for fabricating a semiconductor device may include forming a stacked structure that includes a selector pattern and a sacrificial electrode; forming an insulating layer structured to surround a sidewall of the stacked structure; forming an opening by removing at least part of the sacrificial electrode; and forming an electrode in the opening to a thickness that blocks an entrance of the opening and does not completely fill the opening.

### BRIEF DESCRIPTION OF THE DRAWINGS

FIG. 1 is a perspective view illustrating a semiconductor device based on an embodiment of the disclosed technology.

FIGS. 2A to 2F are cross-sectional views illustrating a semiconductor device and a method for fabricating the semiconductor device based on another embodiment of the disclosed technology.

FIG. 2G is a cross-sectional view illustrating an example of a variable resistance pattern.

FIGS. 3A to 3C are cross-sectional views illustrating a semiconductor device and a method for fabricating the semiconductor device based on another embodiment of the disclosed technology.

FIGS. 4A to 4C are cross-sectional views illustrating a semiconductor device and a method for fabricating the semiconductor device based on another embodiment of the disclosed technology.

FIGS. 5A to 5C are cross-sectional views illustrating a semiconductor device and a method for fabricating the semiconductor device based on another embodiment of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

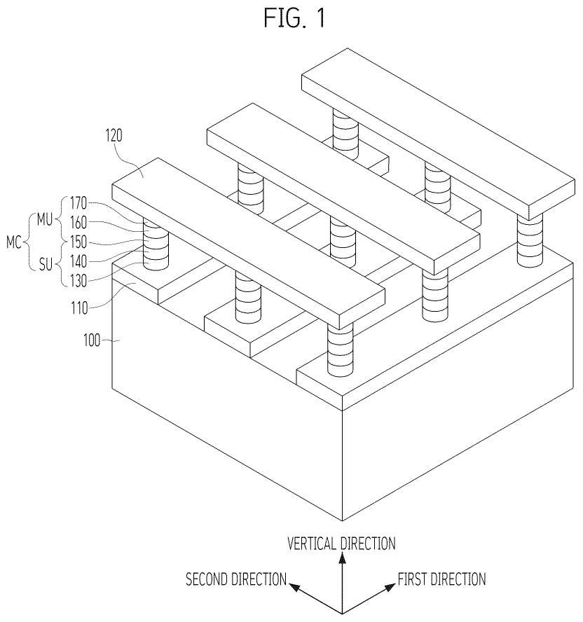

FIG. 1 is a perspective view illustrating a semiconductor device based on an embodiment of the disclosed technology.

Referring to FIG. 1, a semiconductor device based on some embodiments may include a substrate 100, a plurality of first conductive lines 110 disposed over the substrate 100 and extending in a first direction, a plurality of second conductive lines 120 disposed over the first conductive lines 110 and extending in a second direction intersecting the first direction, and a plurality of memory cells MC disposed between the first conductive lines 110 and the second conductive lines 120 and respectively overlapping the intersection regions of the first conductive lines 110 and the second conductive lines 120. Here, the first direction and the second direction may be substantially parallel to the upper surface of the substrate 100. In some implementations, a direction substantially perpendicular to the upper surface of the substrate 100 may be referred to as a vertical direction.

The substrate 100 may include a semiconductor material such as silicon. Additionally, a certain lower structure (not shown) may be formed in the substrate 100. For example, an integrated circuit for driving (e.g., control, select, activate, etc.) the first conductive lines 110 and/or the second conductive lines 120 may be formed in the substrate 100.

The plurality of first conductive lines 110 may be arranged to be spaced apart from each other in the second direction. The first conductive line 110 may include at least one of various conductive materials, for example, a metal such as platinum (Pt), tungsten (W), aluminum (Al), copper (Cu), tantalum (Ta), or titanium (Ti), a metal nitride such as titanium nitride (TIN), tantalum nitride (TaN), or tungsten nitride (WN), or a combination thereof, and may have a single-layer structure or a multi-layer structure.

The plurality of second conductive lines 120 may be arranged to be spaced apart from each other in the first direction. The second conductive line 120 may include at least one of various conductive materials, for example, a metal such as platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), or a combination thereof, and may have a single-layer structure or a multi-layer structure.

Each of the plurality of memory cells MC may include a memory unit MU configured to store data, and a selector unit SU that controls access to the memory unit MU. As an example, the memory cell MC may include a stacked structure that includes a lower electrode layer 130, a selector layer 140, a middle electrode layer 150, a variable resistance layer 160, and an upper electrode layer 170. Here, the selector unit SU may include the lower electrode layer 130, the selector layer 140, and the middle electrode layer 150, and the memory unit MU may include the middle electrode layer 150, the variable resistance layer 160, and the upper electrode layer 170. The middle electrode layer 150 may be shared by the selector unit SU and the memory unit MU.

The lower electrode layer 130 and the upper electrode layer 170 may be located at first and second ends of the memory cell MC, for example, at a bottom end and a top end of the memory cell MC, respectively, and may function to transmit a voltage or current for the operation of the memory cell MC. The middle electrode layer 150 may function to physically separate and electrically connect the selector layer 140 and the variable resistance layer 160. The lower electrode layer 130, the middle electrode layer 150, or the upper electrode layer 170 may include at least one of various conductive materials, for example, a metal such as platinum (Pt), tungsten (W), aluminum (AI), copper (Cu), tantalum (Ta), or titanium (Ti), a metal nitride such as titanium nitride (TiN), tantalum nitride (TaN), or tungsten nitride (WN), or a combination thereof. In some implementations, the lower electrode layer 130, the middle electrode layer 150, or the upper electrode layer 170 may include a carbon electrode.

The selector layer 140 may control access to the variable resistance layer 160, and may prevent or reduce current leakage that may occur between the memory cells 120 sharing the first conductive line 110 or the second conductive line 120. To this end, the selector layer 140 may have a threshold switching characteristic by exhibiting different electrical conducting states in response to an applied voltage with respect to a predetermined threshold voltage: a first electrical conducting state a current is blocked or hardly flows in the selector layer 140 when a magnitude of a voltage applied to the selector layer 140 is less than the predetermined threshold voltage, and a second electrical conducting state in which a current begins to flow through the selector layer 140 and increases rapidly at a voltage equal to or higher than the threshold voltage. That is, the selector layer 140 may be turned on to be in the second electrical conducting state and thus electrically conducting when the applied voltage is higher than the threshold voltage and may be turned off to be in the first electrical conducting state for being non electrically conducting in response to an applied voltage that is lower than the threshold voltage. Because the selector layer 140 exhibits different electrical conducting characteristics, it can be controlled via the applied voltage to be selectively in one of the two different electrical conducting states and thus functions as a selector for selecting whether the memory cell embodying the selector layer 140 is selected or not.

The selector layer 140 may include a diode, an Ovonic threshold switching (OTS) material such as a chalcogenide-based material, a mixed ionic electronic conducting (MIEC) material such as a metal-containing chalcogenide-based material, a metal insulator transition (MIT) material such as NbO₂ or VO₂, or a tunneling insulating material with a relatively wide band gap, such as SiO₂ or Al₂O₃.

In some implementations, the selector layer 140 may include an insulating material doped with a dopant. For example, the insulating material may include a silicon-containing insulating material such as silicon oxide, silicon nitride, or silicon oxynitride, an insulating metal oxide, an insulating metal nitride, or a combination thereof. The dopant may serve to create trap sites that trap conductive carriers moving within the insulating material and provide a passage for the trapped conductive carriers to move again. To form such trap sites, at least one of various elements capable of generating energy levels for accommodating the conductive carriers within the insulating material may be used as the dopant. As an example, when the insulating material contains silicon, the dopant may be a metal with a different valence than silicon, such as gallium (Ga), boron (B), indium (In), phosphorus (P), arsenic (As), antimony (Sb), germanium (Ge), carbon (C), tungsten (W), or a combination thereof. Alternatively, when the insulating material contains a metal, the dopant may include another metal having a different valence than the metal, or silicon. As an example, the selector layer 140 may include silicon dioxide (SiO₂) doped with arsenic (As). When a voltage higher than the threshold voltage is applied to the selector layer 140, the conductive carriers move through the trap sites, thereby creating an “on” state in which a current flows through the selector layer 140. When the voltage applied to the selector layer 140 decreases below the threshold voltage, the conductive carriers do not move and enters an “off” state in which no current flows.

The variable resistance layer 160 may be a part of a memory cell MC that functions to store data. To this end, the variable resistance layer 160 may have a variable resistance characteristic that switches between different resistance states depending on a voltage applied to the variable resistance layer 160. The variable resistance layer 160 may include at least one of various materials that can be used in resistive random access memory (RRAM), phase-change random access memory (PRAM), ferroelectric random access memory (FRAM), magnetic random access memory (MRAM), for example, a metal oxide such as a transition metal oxide or a perovskite-based material, a phase change material such as a chalcogenide-based material, a ferroelectric material, or a ferromagnetic material, and may have a single-layer structure or a multi-layer structure. As an example, the variable resistance layer 160 may include a magnetic tunnel junction structure that can store data by switching between different resistance states by changing the magnetization direction. When the variable resistance layer 160 has a high resistance state, the data bit stored in the memory cell MC may correspond to “0,” and when the variable resistance layer 160 has a low resistance state, the data bit stored in the memory cell MC may correspond to “1.”

This memory cell MC may have a pillar shape that overlaps the intersection region of the first conductive line 110 and the second conductive line 120. Although FIG. 1 illustrates the memory cell MC as having a cylindrical shape, the disclosed technology is not limited thereto, and the memory cell MC may have a shape different from the cylindrical shape such as a square pillar shape, a rectangular pillar shape, or an elliptical pillar shape. In an implementation, the layers 130 to 170 forming the memory cell MC may include sidewalls aligned with each other by performing a patterning process using a single mask. In some implementations, when the variable resistance layer 160 has a multi-layer structure such as a magnetic tunnel junction structure, it may be difficult to collectively etch the layers 130 to 170 forming the memory cell MC using a single mask. In this case, the selector layer 140 and the variable resistance layer 160 may be patterned separately using different masks, so they may have sidewalls that are not aligned with each other. The lower electrode layer 130 may be patterned together with the selector layer 140, the upper electrode layer 170 may be patterned together with the variable resistance layer 160, and the middle electrode layer 150 may be patterned together with one of the selector layer 140 and the variable resistance layer 160. In some embodiments of the disclosed technology, the term “pattern” can be used to indicate a material layer that is formed through a patterning process using one or more masks.

Additionally, the layer structure of the memory cell MC is not limited to what is shown in the figures. The stacking order of the layers of the memory cell MC may be changed, one or more of the layers of the memory cell MC may be omitted, or one or more additional layers may be added to the memory cell MC. As an example, one or more of the lower electrode layer 130, the middle electrode layer 150, and the upper electrode layer 170 may be omitted. Alternatively, the positions of the selector layer 140 and the variable resistance layer 160 may be reversed with each other. That is, in some implementations, the selector layer 140 may be located over the middle electrode layer 150, and the variable resistance layer 160 may be located under the middle electrode layer 150. Alternatively, one or more layers (not shown) may be added to the memory cell MC to improve the process or the characteristic of the memory cell MC.

In some implementations, there may be restrictions on materials used, thickness, etc. with respect to the middle electrode layer 150 located between the selector layer 140 and the variable resistance layer 160, due to manufacturing process issues, such as the difficulty of the patterning process and the diffusion of the dopant upon contact with the selector layer 140. For these reasons, it may be difficult to form the middle electrode layer 150 with desired characteristics, such as a desired bandwidth and/or a desired resistance. For example, when it is necessary to increase the resistance of the middle electrode layer 150 above a predetermined value in order to lower the hold current of the selector layer 140, such resistance increase may be difficult due to restrictions on the middle electrode layer 150. For reference, the hold current of the selector layer 140 may be a minimum current for maintaining the selector layer 140 in the on state. If the hold current increases, the operating current, such as the write current or the read current, may become lower than the hold current, and thus, an oscillation phenomenon in which the turn-on and turn-off of the selector layer 140 is repeated, and accordingly an operation failure due to the oscillation phenomenon may occur. Accordingly, it may be desirable to reduce the hold current of the selector layer 140 as much as possible. If the selector layer 140 is connected in series with a material having a relatively high resistance, it may be possible to reduce the hold current of the selector layer 140. For example, if the resistance of the middle electrode layer 150 increases, the hold current of the selector layer 140 may decrease. This may result in an overall decrease in the magnitude of the current flowing through the selector layer 140 due to the voltage divider effect, and accordingly, the hold current, which is the minimum current required to maintain the on state of the selector layer 140, may also decrease.

As will be discussed below, the disclosed technology can be implemented in some embodiments to freely adjust the material or the thickness of the middle electrode layer 150 in a semiconductor device by overcoming restrictions on the middle electrode layer 150.

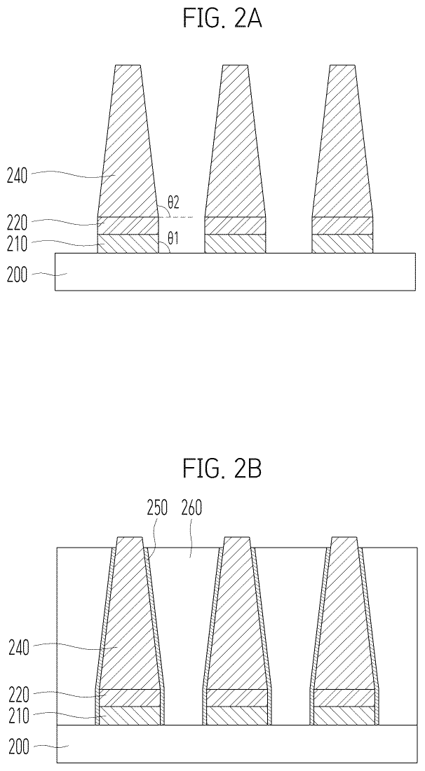

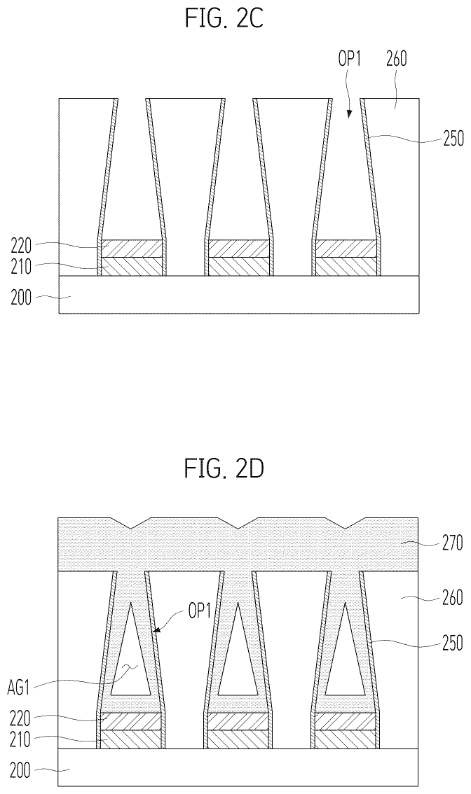

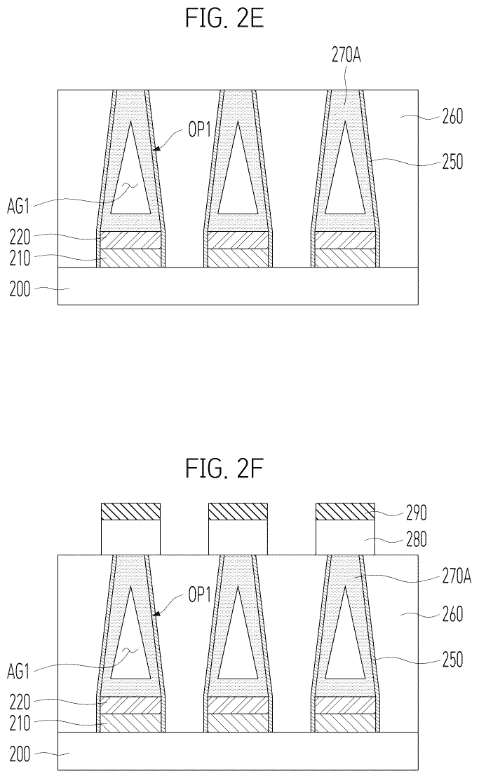

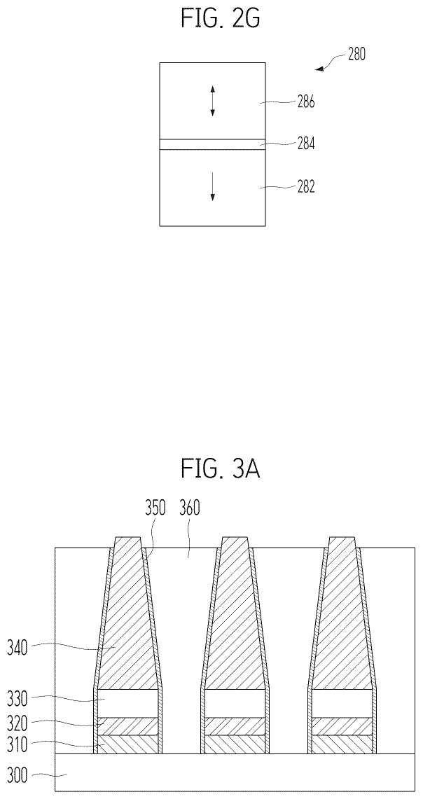

FIGS. 2A to 2F are cross-sectional views illustrating a semiconductor device and a method for fabricating the semiconductor device based on another embodiment of the disclosed technology. Detailed description of parts that are substantially the same as the above-described embodiment will be omitted.

The disclosed technology can be implemented in some embodiments to provide the fabricating method of the semiconductor device as will be described below.

Referring to FIG. 2A, a substrate 200 in which a predetermined lower structure is formed may be provided. The substrate 200 may include at least one of various circuits. For example, the substrate 200 may include a conductive line similar to the first conductive line 110 of

FIG. 1 described above.

Subsequently, a stacked structure of a lower electrode 210, a selector pattern 220, and a sacrificial middle electrode 240 may be formed over the substrate 200. The stacked structure may be formed by sequentially forming a lower electrode material, a selector material, and a sacrificial electrode material over the substrate 200, and selectively etching them. The stacked structure may have a pillar shape. In some embodiments, three stacked structures are shown spaced apart from each other, but the disclosed technology is not limited thereto, and the number of layers or the arrangement of layers in the stacked structures may be modified in various ways.

In some implementations, the lower electrode 210 and the selector pattern 220 may be formed of the same material as the lower electrode layer 130 and the selector layer 140 of FIG. 1, respectively.

The sacrificial middle electrode 240 may include at least one of various materials that can be easily removed in a subsequent removal process. Furthermore, the sacrificial middle electrode 240 may be formed of the same thickness and the same material as the thickness and the material of a commonly used middle electrode. This may be because the material and the thickness of the commonly used middle electrode have already been appropriately adjusted in consideration of the difficulty of the patterning process, and thus, the etching process for forming the sacrificial middle electrode 240 may be facilitated. As an example, the sacrificial middle electrode 240 may include titanium nitride. In addition, because the sacrificial middle electrode 240 functions as an etch barrier together with a mask pattern (not shown) used during the etching process for forming the lower electrode 210 and the selector pattern 220, the sacrificial middle electrode 240 may be formed to have a thickness greater than that of the lower electrode 210.

The sidewall slope of the sacrificial middle electrode 240 may be greater than the sidewall slope of each of the lower electrode 210 and the selector pattern 220. That is, the angle θ1 formed by the sidewall of each of the lower electrode 210 and the selector pattern 220 with respect to the upper surface of the substrate 200 may be smaller than the angle θ2 formed by the sidewall of the sacrificial middle electrode 240 with respect to the upper surface of the substrate 200. The angle θ1 may be, for example, 90 degrees, and the angle θ2 may be, for example, an obtuse angle. Accordingly, the width of the sacrificial middle electrode 240 may increase from top to bottom, and the width of the uppermost portion of the sacrificial middle electrode 240 may be smaller than the width of the lower electrode 210 and/or the selector pattern 220. The sidewall slope of the sacrificial middle electrode 240 may be formed naturally because the thickness of the sacrificial middle electrode 240 is much greater than the thickness of each of the lower electrode 210 and the selector pattern 220. Alternatively, the sidewall slope of the sacrificial middle electrode 240 may be intentionally formed by adjusting the process recipe. However, the disclosed technology is not limited to the examples discussed above, and the sidewall slope of the sacrificial middle electrode 240 may be substantially the same as the sidewall slope of the lower electrode 210 and/or the selector pattern 220.

Referring to FIG. 2B, a spacer 250 may be formed over the sidewall of the stacked structure of the lower electrode 210, the selector pattern 220, and the sacrificial middle electrode 240. The spacer 250 may serve to protect the selector pattern 220 during a subsequent forming process of an interlayer insulating layer 260, and/or prevent the interlayer insulating layer 260 from being lost during a subsequent removal process of the sacrificial middle electrode 240. The spacer 250 may be conformally formed with a thin thickness that does not completely fill the space between the stacked structures of the lower electrode 210, the selector pattern 220, and the sacrificial middle electrode 240. For example, the spacer 250 may be formed by deposition of an insulating material such as silicon nitride. For example, the spacer 250 may be omitted. In this case, the interlayer insulating layer 260 may be in direct contact with the sidewall of the stacked structure of the lower electrode 210, the selector pattern 220, and the sacrificial middle electrode 240.

Subsequently, the interlayer insulating layer 260 may be formed to fill a gap between the stacked structures of the lower electrode 210, the selector pattern 220, and the sacrificial middle electrode 240. The interlayer insulating layer 260 may include an insulating material such as silicon oxide. In addition, the interlayer insulating layer 260 may be formed by depositing an insulating material thick enough to cover the stacked structures of the lower electrode 210, the selector pattern 220, and the sacrificial middle electrode 240 while sufficiently filling the space between the stacked structures, and performing a planarization process such as etch-back or chemical mechanical polishing (CMP) process on the insulating material until the upper surface of the sacrificial middle electrode 240 is exposed. During this planarization process, the height of the interlayer insulating layer 260 may be lowered to a certain degree from the upper surface of the sacrificial middle electrode 240, and thus, the upper end of the sacrificial middle electrode 240 may protrude above the interlayer insulating layer 260. During this planarization process, the height of the spacer 250 formed of an insulating material may also be lowered together with the interlayer insulating layer 260, and may have an upper surface located at substantially the same height as the upper surface of the interlayer insulating layer 260.

Referring to FIG. 2C, the sacrificial middle electrode 240 may be removed. The sacrificial middle electrode 240 may be removed using a wet dip-out method. When the sacrificial middle electrode 240 includes titanium nitride, the sacrificial middle electrode 240 may be removed by a dip-out method using hydrogen peroxide (H₂O₂). In this case, only the sacrificial middle electrode 240 may be selectively removed without substantial loss to the selector pattern 220, the spacer 250, and/or the interlayer insulating layer 260 that are located around the sacrificial middle electrode 240.

A space formed by removal of the sacrificial middle electrode 240 will hereinafter be referred to as an opening OP1. The opening OP1 may have the narrowest width at the uppermost portion, that is, at the entrance of the opening OP1, and may have a width that increases from top to bottom. The width of the entrance of the opening OP1 may be smaller than the width of the lower electrode 210 and/or the width of the selector pattern 220. The upper surface of the selector pattern 220 may be exposed by forming the opening OP1.

Referring to FIG. 2D, a middle electrode layer 270 may be formed by depositing a conductive material over the process result of FIG. 2C. The middle electrode layer 270 may be formed along the sidewall and the lower surface of the opening OP1, that is, the upper surface of the selector pattern 220 to a thickness that does not completely fill the opening OP1. Further, the middle electrode layer 270 may be formed to a thickness that blocks the entrance of the opening OP1. In some implementations, the uppermost portion of the opening OP1, that is, the entrance of the opening OP1, has the narrowest width, and thus it may be possible to form the middle electrode layer 270 that does not completely fill the opening OP1 while blocking the entrance of the opening OP1. The thickness of the middle electrode layer 270 may be equal to or more than 1/2 of the width of the uppermost portion of the opening OP1.

The deposition of the conductive material for forming the middle electrode layer 270 may be performed using a method such as physical vapor deposition (PVD) or atomic layer deposition (ALD). In addition, the conductive material for forming the middle electrode layer 270 may include a metal such as iridium (Ir), platinum (Pt), tungsten (W), aluminum (Al), copper (Cu), tantalum (Ta), or titanium (Ti), a metal nitride such as titanium nitride (TiN), tantalum nitride (TaN), or tungsten nitride (WN), a non-metal such as polysilicon doped with impurities, or a combination thereof. The impurities may include carbon, boron, or others.

As a result of this process, the middle electrode layer 270 may be formed to have a hollow shape in the opening OP1 (under the entrance of the opening OP1). In other words, an air gap AG1 surrounded by the middle electrode layer 270 may be formed in the opening OP1. The air gap AG1 may be in a vacuum state or filled with a gas such as air. The size of the air gap AG1 may be adjusted depending on the thickness of the middle electrode layer 270. That is, as the thickness of the middle electrode layer 270 increases, the size of the air gap AG1 may decrease, and as the thickness of the middle electrode layer 270 decreases, the size of the air gap AG1 may increase. The thickness of the middle electrode layer 270 may be adjusted according to the process recipe, such as deposition time.

Referring to FIG. 2E, a planarization process, such as etch-back or CMP, may be performed on the middle electrode layer 270 to expose the upper surface of the interlayer insulating layer 260, thereby forming a middle electrode 270A filled in the opening OP1. Since this planarization process, unlike the process of FIG. 2B, is performed on the middle electrode layer 270 containing a metal, etc., the middle electrode 270A may have an upper surface that is substantially flat with the upper surface of the interlayer insulating layer 260. That is, the upper surface of the middle electrode 270A and the upper surface of the interlayer insulating layer 260 may be positioned at substantially the same height in the vertical direction. During etch-back or CMP, insulating materials are more likely to dent than metallic materials, while metallic materials are less likely to dent than insulating materials.

Referring to FIG. 2F, a variable resistance pattern 280 and an upper electrode 290 may be formed over the structure formed as a result of the process in FIG. 2E.

The stacked structure of the variable resistance pattern 280 and the upper electrode 290 may be in contact with the middle electrode 270A to be electrically connected to the middle electrode 270A. The variable resistance pattern 280 and the upper electrode 290 may be formed by depositing a material for forming the variable resistance pattern 280 and a conductive material for forming the upper electrode 290 over the process result of FIG. 2E, and selectively etching them. Since the variable resistance pattern 280 and the upper electrode 290 are patterned using another mask different from a mask used to form the lower electrode 210, the selector pattern 220, and the middle electrode 270A, the sidewalls of the variable resistance pattern 280 and the upper electrode 290 may not be aligned with the sidewalls of the lower electrode 210, the selector pattern 220, and the middle electrode 270A.

In some embodiments, as discussed above, the variable resistance pattern 280 is formed over the selector pattern 220, but the disclosed technology is not limited thereto. In another embodiment, the variable resistance pattern 280 may be formed under the lower electrode 210, before forming the lower electrode 210. Therefore, the variable resistance pattern 280 may be formed under the selector pattern 220. Even in this case, the variable resistance pattern 280 may be electrically connected to the selector pattern 220 through the lower electrode 210.

As an example, the variable resistance pattern 280 may include a magnetic tunnel junction structure, which will be described with reference to FIG. 2G.

FIG. 2G is a cross-sectional view illustrating an example of a variable resistance pattern.

Referring to FIG. 2G, the variable resistance pattern 280 may be a magnetic tunnel junction structure, and may include a pinned layer 282, a tunnel barrier layer 284, and a free layer 286.

The pinned layer 282 may be a layer that has a fixed magnetization direction that can be compared to the magnetization direction of the free layer 286, and may also be called a reference layer.

The free layer 286 may be a layer that can store different data by having a changeable magnetization direction, and may also be called a storage layer. The tunnel barrier layer 284 may physically separate the pinned layer 282 and the free layer 286, and may enable tunneling of electrons between them. Each of the pinned layer 282 and the free layer 286 may have a single-layer structure or multi-layer structure including a ferromagnetic material. As an example, each of the pinned layer 282 and the free layer 286 may include an alloy containing Fe, Ni, or Co as a main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, or Co—Fe—B alloy, or at least one of stacked structures of Co/Pt and Co/Pd. The tunnel barrier layer 284 may have a single-layer structure or multi-layer structure including an insulating material. As an example, the tunnel barrier layer 284 may include an insulating oxide such as MgO, CaO, SrO, TiO, VO, or NbO.

In this magnetic tunnel junction structure, the magnetization direction of the free layer 286 may vary depending on the applied voltage or current. When the magnetization direction of the free layer 286 is parallel to the magnetization direction of the pinned layer 282, the magnetic tunnel junction structure may have a low resistance state and, for example, may store data bit “1.” On the other hand, when the magnetization direction of the free layer 286 is anti-parallel to the magnetization direction of the pinned layer 282, the magnetic tunnel junction structure may have a high resistance state and, for example, may store data bit “0.”

As long as the magnetic tunnel junction structure includes the pinned layer 282, the free layer 286, and the tunnel barrier layer 284 therebetween, the layer structure of the magnetic tunnel junction structure may be modified in various ways. As an example, the positions of the pinned layer 282 and the free layer 286 may be reversed with each other. Alternatively, as an example, although not shown, one or more layers to improve the characteristics of the magnetic tunnel junction structure may be further added to the magnetic tunnel junction structure.

It may be important for this magnetic tunnel junction structures to be formed on a flat surface, that is, a planarized surface. If the magnetic tunnel junction structure is not formed on a flat surface and bending occurs in the tunnel barrier layer 284, a defect known as Neel coupling may occur and the switching characteristic of the magnetic tunnel junction structure may deteriorate.

Referring again to FIG. 2F, when the variable resistance pattern 280 includes a magnetic tunnel junction structure, deterioration of the characteristic of the variable resistance pattern 280 may be prevented and/or reduced because the variable resistance pattern 280 is located on the upper surface of the middle electrode 270A and the upper surface of the interlayer insulating layer 260 that form a substantially flat surface.

The semiconductor device may be fabricated using the above-described method.

Referring again to FIG. 2F, the semiconductor device implemented based on some embodiments may include the substrate 200, the stacked structure including the lower electrode 210, the selector pattern 220, and the middle electrode 270A and disposed over the substrate 200, the spacer 250 formed over the sidewall of the stacked structure, the interlayer insulating layer 260 that fills the space between the stacked structures of the lower electrode 210, the selector pattern 220, and the middle electrode 270A, and the variable resistance pattern 280 and the upper electrode 290 formed over the middle electrode 270A and the interlayer insulating layer 260.

Here, the spacer 250 or the interlayer insulating layer 260 when the spacer 250 is omitted, may surround the sidewall of the selector pattern 220, and may provide the opening OP1 located over the selector pattern 220. The opening OP1 may have the smallest width at the uppermost portion, that is, at the entrance of the opening OP1, and may have a width that increases from top to bottom. The middle electrode 270A may be formed to a thickness that blocks the entrance of the opening OP1 and does not completely fill the opening OP1, and accordingly, the air gap AG1 surrounded by the middle electrode 270A may be formed in the opening OP1.

In some embodiments, the semiconductor device may include the components discussed above with respect to the fabricating method.

As explained above, since the middle electrode 270A is formed without using an etching process, the middle electrode 270A may not be limited by the etching process. Accordingly, various desired materials, such as a material with a high bandwidth and a poor gap-fill characteristic, may be used as the middle electrode 270A.

Additionally, because the thickness of the middle electrode 270A may be easily adjusted, it may be possible to easily adjust the resistance of the middle electrode 270A to a desired level. If the thickness of the middle electrode 270A increases, the resistance of the middle electrode 270A may decrease, and if the thickness of the middle electrode 270A decreases, the resistance of the middle electrode 270A may increase. As an example, if it is desired to increase the resistance of the middle electrode 270A to reduce the hold current of the selector pattern 220, the thickness of the middle electrode 270A may be reduced. Alternatively, as another example, if it is desired to make the current flow through the middle electrode 270A more smoothly, the thickness of the middle electrode 270A may be increased.

Furthermore, since the middle electrode 270A is formed by being filled in the opening OP1 of the interlayer insulating layer 260 through a planarization process, it may be possible to easily form a flat surface formed by the upper surface of the middle electrode 270A and the upper surface of the interlayer insulating layer 260. As a result, the variable resistance pattern 280 may be located on a flat surface, and accordingly, it may be possible to secure the characteristics of the variable resistance pattern 280. As an example, when the variable resistance pattern 280 includes a magnetic tunnel junction structure, defects such as Neel coupling may be prevented.

As a result, it may be possible to secure the required characteristics of the memory cell and prevent and/or reduce the occurrence of defects.

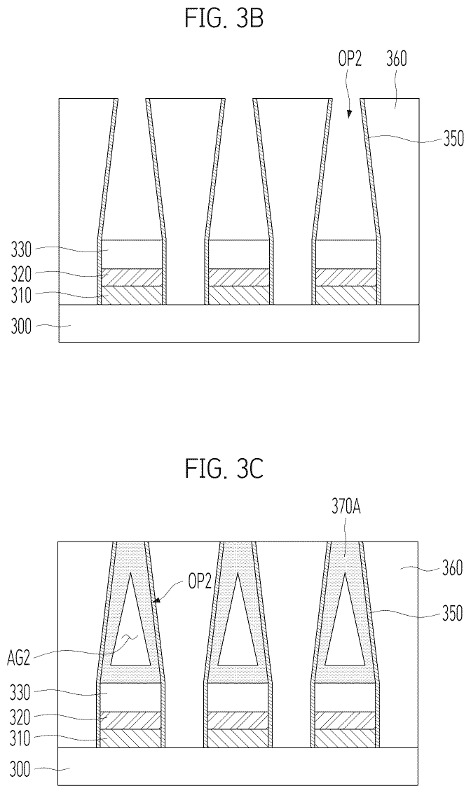

FIGS. 3A to 3C are cross-sectional views illustrating a semiconductor device and a method for fabricating the semiconductor device based on another embodiment of the disclosed technology. The description will focus on differences from the above-described embodiments.

Referring to FIG. 3A, a stacked structure of a lower electrode 310, a selector pattern 320, a buffer pattern 330, and a sacrificial middle electrode 340 may be formed over a substrate 300 in which a predetermined lower structure is formed.

Here, the buffer pattern 330 may serve to protect the selector pattern 320 when the sacrificial middle electrode 340 is removed later. To this end, the buffer pattern 330 may include a material having an etch rate different from that of the sacrificial middle electrode 340 during a wet dip-out process for removal of the sacrificial middle electrode 340. In some embodiments, since the buffer pattern 330 is not removed but is interposed between a middle electrode (see 370A in FIG. 3C) and the selector pattern 320, the buffer pattern 330 may have a conductive property for electrical connection between the middle electrode 370A and the selector pattern 320. In addition, the buffer pattern 330 may include a material with a relatively high specific resistance. For example, the buffer pattern 330 may include a material having a greater specific resistance than a material for forming the middle electrode 370A. In this case, the buffer pattern 330 may function as a kind of resistance layer that reduces the hold current of the selector pattern 320. As an example, the buffer pattern 330 may include amorphous carbon. However, the disclosed technology is not limited to the examples discussed above, and the material for forming the buffer pattern 230 may be variously modified as long as the buffer pattern 330 includes a material having a different etch rate than the selector pattern 320.

In some implementations, a spacer 350 may be formed over the sidewall of the stacked structure of the lower electrode 310, the selector pattern 320, the buffer pattern 330, and the sacrificial middle electrode 340, and then, an interlayer insulating layer 360 may be formed to fill the space between the stacked structures.

Referring to FIG. 3B, an opening OP2 may be formed by removing the sacrificial middle electrode 340. The sacrificial middle electrode 340 may be removed using a wet dip-out method. When the sacrificial middle electrode 340 is removed, the buffer pattern 330 may cover the upper surface of the selector pattern 320, so the selector pattern 320 may not be exposed to a chemical used in the wet dip-out process and may be protected. Accordingly, when using the buffer pattern 330, it may be advantageous to secure the characteristics of the selector pattern 320.

Referring to FIG. 3C, a middle electrode 370A may be formed along the sidewall and the lower surface of the opening OP2, that is, the upper surface of the buffer pattern 330, and may have a thickness that does not completely fill the opening OP2. The middle electrode 370A may block the entrance of the opening OP2.

As a result of this process, the middle electrode 370A having a hollow shape may be formed in the opening OP2. In other words, an air gap AG2 surrounded by the middle electrode 370A may be formed in the opening OP2.

In this way, all the advantages of the above-described embodiments can be obtained. In addition, by interposing the buffer pattern 330 between the middle electrode 370A and the selector pattern 320, there may be an advantage of protecting the selector pattern 320 when forming the opening OP2 which will be filled with the middle electrode 370A. Furthermore, by adjusting the thickness of the middle electrode 370A and the resistance of the buffer pattern 330, the characteristics of the selector pattern 320, such as hold current, may be adjusted more precisely.

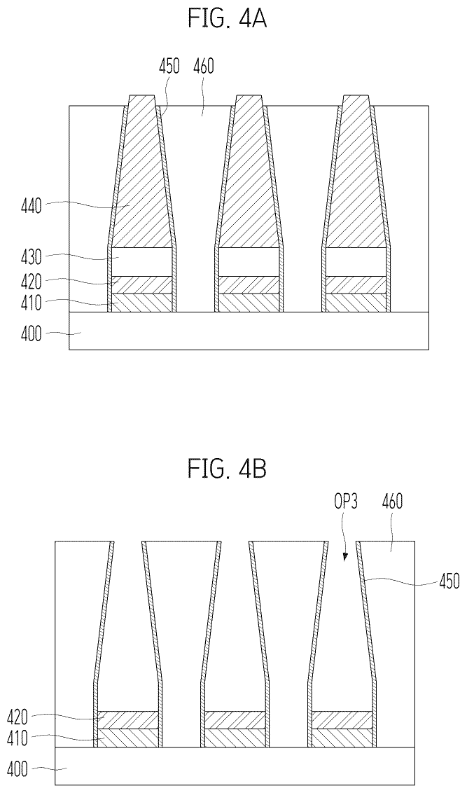

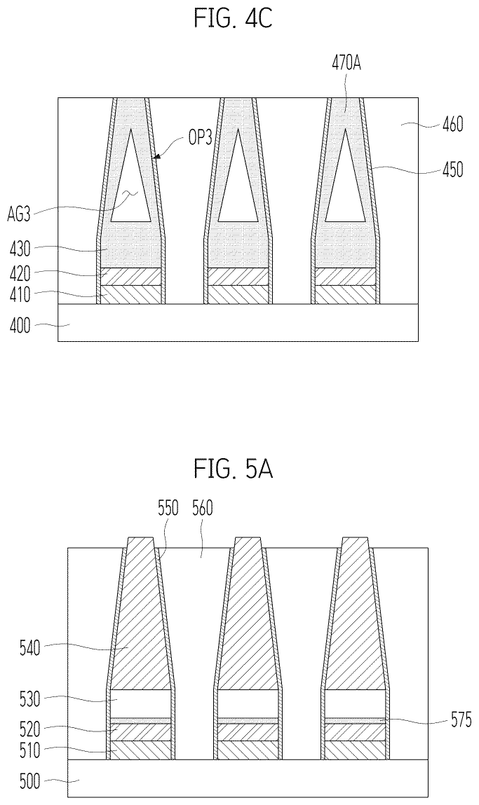

FIGS. 4A to 4C are cross-sectional views illustrating a semiconductor device and a method for fabricating the semiconductor device based on another embodiment of the disclosed technology. The description will focus on differences from the above-described embodiments.

Referring to FIG. 4A, a stacked structure of a lower electrode 410, a selector pattern 420, a buffer pattern 430, and a sacrificial middle electrode 440 may be formed over the substrate 400 in which a predetermined lower structure is formed.

Here, the buffer pattern 430 may serve to protect the selector pattern 420 when the sacrificial middle electrode 440 is removed later. To this end, the buffer pattern 430 may include a material having an etch rate different from that of the sacrificial middle electrode 440 during a wet dip-out process for removal of the sacrificial middle electrode 440. Since the buffer pattern 430 is removed based on some embodiments, the buffer pattern 430 may not need to have a conductive property, and may use at least one of various materials such as a conductive material or an insulating material. The buffer pattern 430 may have a material that can be easily removed.

In some implementations, a spacer 450 may be formed over the sidewall of the stacked structure of the lower electrode 410, the selector pattern 420, the buffer pattern 430, and the sacrificial middle electrode 440, and then, an interlayer insulating layer 460 may be formed to fill the space between the stacked structures.

Referring to FIG. 4B, the sacrificial middle electrode 440 may be removed, and then, the buffer pattern 430 exposed by removal of the sacrificial middle electrode 440 may be removed, thereby forming an opening OP3. The sacrificial middle electrode 440 may be removed using a wet dip-out method. The buffer pattern 430 may be removed through at least one of various removal methods. When the buffer pattern 430 includes carbon, the buffer pattern 430 may be removed through a strip process containing oxygen. The opening OP3 may also have a minimum width at the uppermost portion, that is, at the entrance.

Referring to FIG. 4C, a middle electrode 470A may be formed along the sidewall and the lower surface of the opening OP3, that is, the upper surface of the selector pattern 420, and may have a thickness that does not completely fill the opening OP3. The middle electrode 470A may block the entrance to the opening OP3.

As a result of this process, the middle electrode 470A having a hollow shape may be formed in the opening OP3. In other words, an air gap AG3 surrounded by the middle electrode 470A may be formed in the opening OP3.

In this way, all the advantages of the above-described embodiments may be obtained. In addition, by interposing the buffer pattern 430 between the middle electrode 470A and the selector pattern 420, there may be an advantage of protecting the selector pattern 420 when removing the sacrificial middle electrode 440.

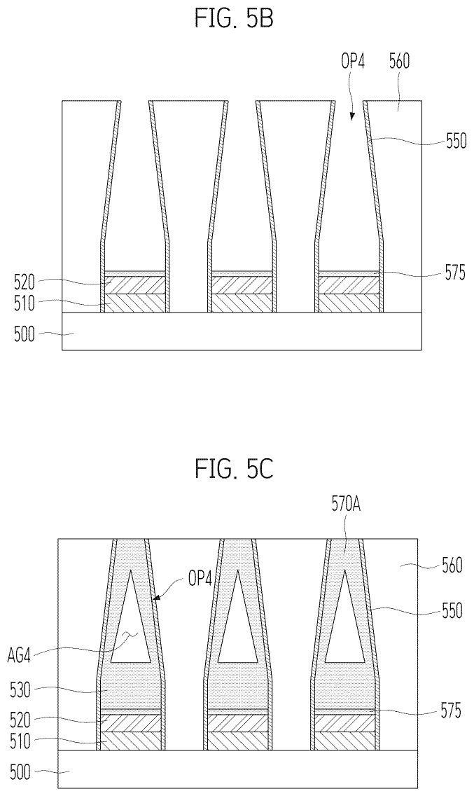

FIGS. 5A to 5C are cross-sectional views illustrating a semiconductor device and a method for fabricating the semiconductor device based on another embodiment of the disclosed technology. The description will focus on differences from the above-described embodiments.

Referring to FIG. 5A, a stacked structure of a lower electrode 510, a selector pattern 520, an additional electrode 575, a buffer pattern 530, and a sacrificial middle electrode 540 may be formed over a substrate 500 in which a predetermined lower structure is formed.

Here, the additional electrode 575 may serve to protect the selector pattern 520 when the buffer pattern 530 is removed later, and may serve as an electrode located over the selector pattern 520, together with a middle electrode (see 570A in FIG. 5C). The additional electrode 575 may include substantially the same material as the middle electrode 570A.

Subsequently, a spacer 550 may be formed over the sidewall of the stacked structure of the lower electrode 510, the selector pattern 520, the additional electrode 575, the buffer pattern 530, and the sacrificial middle electrode 540, and then, an interlayer insulating layer 560 may be formed to fill the space between the stacked structures.

Referring to FIG. 5B, the sacrificial middle electrode 540 may be removed, and then, the buffer pattern 530 exposed by removal of the sacrificial middle electrode 540 may be removed, thereby forming an opening OP4. When the buffer pattern 530 is removed, the additional electrode 575 may protect the selector pattern 520.

Referring to FIG. 5C, the middle electrode 570A may be formed along the sidewall and the lower of the opening OP4, that is, the upper surface of the additional electrode 575, and may have a thickness that does not completely fill the opening OP4. The middle electrode 570A may block the entrance to the opening OP4.

As a result of this process, the middle electrode 570A having a hollow shape may be formed in the opening OP4. In other words, an air gap AG4 surrounded by the middle electrode 570A may be formed in the opening OP4.

In this way, all the advantages of the above-described embodiments may be obtained. In addition, by interposing the buffer pattern 530 between the middle electrode 570A and the selector pattern 520, there may be an advantage of protecting the selector pattern 520 when the sacrificial middle electrode 540 is removed. In addition, by interposing the additional electrode 575 between the buffer pattern 530 and the selector pattern 520, there may be an advantage of protecting the selector pattern 520 when the buffer pattern 530 is removed. Since the additional electrode 575 performs an electrode function together with the middle electrode 570A, a separate removal process of the additional electrode 575 may not be required.

In some embodiments of the disclosed technology, it may be possible to secure the characteristics of the memory cell and reducing and/or preventing occurrence of defects.

While the disclosed technology has been illustrated and described with respect to specific embodiment, it should be understood that various enhancements and modifications of the disclosed embodiments and other embodiments may be made based on what is described and illustrated in this patent document.

What is claimed is:

1. A semiconductor device comprising:
a selector pattern configured to exhibit a threshold switching behavior by exhibiting different electrical conducting characteristics in response to an applied voltage with respect to a threshold voltage;
an insulating layer structured to surround a sidewall of the selector pattern and include an opening disposed within the insulating layer over the selector pattern; and
an electrode formed in the opening to a thickness that blocks an entrance of the opening and does not completely fill the opening.

2. The semiconductor device according to claim 1, further comprising:
an air gap surrounded by the electrode in the opening.

3. The semiconductor device according to claim 1, wherein the entrance of the opening has a width that is narrower than a width of a lower surface of the opening.

4. The semiconductor device according to claim 1, wherein the opening has a width that increases from the entrance of the opening to a top surface of the selector pattern.

5. The semiconductor device according to claim 1, further comprising:
a buffer pattern disposed between the selector pattern and the electrode.

6. The semiconductor device according to claim 5, wherein the buffer pattern includes a material having a higher specific resistance than the electrode.

7. The semiconductor device according to claim 1, wherein the electrode and the insulating layer have a planarized upper surface.

8. The semiconductor device according to claim 7, further comprising:
a magnetic tunnel junction structure formed over the planarized upper surface and electrically connected to the electrode.

9. A method for fabricating a semiconductor device, comprising:
forming a stacked structure that includes a selector pattern and a sacrificial electrode, wherein the selector pattern is configured to exhibit a threshold switching behavior by exhibiting different electrical conducting characteristics in response to an applied voltage with respect to a threshold voltage;
forming an insulating layer structured to surround a sidewall of the stacked structure;
forming an opening by removing at least part of the sacrificial electrode; and
forming an electrode in the opening to a thickness that blocks an entrance of the opening and does not completely fill the opening.

10. The method according to claim 9, wherein an uppermost portion of the sacrificial electrode has a width that is narrower than a width of a lower surface of the opening.

11. The method according to claim 9, wherein the sacrificial electrode has a width that increases from the entrance of the opening to a top surface of the selector pattern.

12. The method according to claim 9, wherein the sacrificial electrode includes titanium nitride, and
the at least part of the sacrificial electrode is removed by using hydrogen peroxide.

13. The method according to claim 9, wherein the forming of the electrode comprises:
depositing a conductive material over the insulating layer with a thickness that blocks the entrance of the opening and does not completely fill the opening; and
performing a planarization process to expose an upper surface of the insulating layer.

14. The method according to claim 13, wherein the electrode includes an upper surface that is planarized with the upper surface of the insulating layer, and
wherein the method further comprises:
forming a magnetic tunnel junction structure electrically connected to the electrode over the upper surface of the insulating layer and the upper surface of the electrode, after forming the electrode.

15. The method according to claim 9, wherein the stacked structure further includes a buffer pattern interposed between the sacrificial electrode and the selector pattern.

16. The method according to claim 15, wherein the buffer pattern includes amorphous carbon.

17. The method according to claim 15, wherein while the opening is formed, the buffer pattern is maintained.

18. The method according to claim 15, wherein while the opening is formed, at least part of the buffer pattern is removed.

19. The method according to claim 18, wherein the stacked structure further includes an additional electrode interposed between the buffer pattern and the selector pattern, and
while the opening is formed, the additional electrode is maintained.

20. The method according to claim 19, wherein the electrode and the additional electrode include a same material.
